(19) United States
(12) Patent Application Publication
(10) Pub. No.: US 2004/0229419 A1
(43) Pub. Date: Nov. 18, 2004

(54) Gas processing device and method of fabricating a semiconductor device

(75) Inventor: Isamu Namose, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/769,899

(22) Filed: Feb. 3, 2004

(30) Foreign Application Priority Data
Feb. 4, 2003 (JP) 2003-026957

(51) Int. Cl. H01L 21/8238

(52) U.S. Cl. 438/202

(57) ABSTRACT

A gas processing device includes a sub pump that reduces the pressure of gases containing reactive components and exhausts them, a plasma decomposition device that decomposes the reactive components comprised within the gases exhausted from the sub pump then exhausts them, and a main pump that reduces the pressure of the gases exhausted from the plasma decomposition device then exhausts them.

Japanese Patent Application No. 2003-26957, filed on Feb. 4, 2003, is hereby incorporated by reference in its entirety.

### BACKGROUND OF THE INVENTION

The present invention relates to a gas processing device and a method of fabricating a semiconductor device which uses that gas processing device.

A plasma decomposition device is used as a device for breaking down or decomposing reactive components in gaseous form. Such a plasma decomposition device can break organic halogen compounds such as perfluro-compound (PFC) gases and chlorofluoro-compound (CFC) gases down into gases with of lower molecular weights. These gases (organic halogen compounds) are known as greenhouse-effect gases. These greenhouse-effect gases are said to contribute to global warming. There are international demands to check the release of such gases into the atmosphere, to suppress the advance of global warming.

These gases are currently used as coolants in refrigerators, air-conditioners, and automobiles, and the release of those gases into the atmosphere when such appliances are scrapped causes a large problem. These gases are also used in the fabrication of semiconductor devices, so there are demands to process these gases suitably after use. A processing method that uses a plasma decomposition device as a means of breaking down such gases, as described above, is known. This plasma decomposition device is also widely used as means of breaking down harmful substances other than the above-mentioned gases.

A general-purpose plasma decomposition device has been disclosed in Japanese Patent Application Laid-Open No. 2001-274000 (FIGS. 9 and 10).

### BRIEF SUMMARY OF THE INVENTION

The present invention may provide a gas processing device that has superlative capabilities concerning the decomposition of reactive components within gases, and a method of fabricating a semiconductor device that uses that gas processing device.

According to one aspect of the present invention, there is provided a gas processing device comprising:

a sub pump which reduces the pressure of gases containing reactive components and then exhausts the gases;

a plasma decomposition device which decomposes the reactive components contained in the gases exhausted from the sub pump and then exhausts the gases; and

a main pump which reduces the pressure of the gases exhausted from the plasma decomposition device and then exhausts the gases.

According to another aspect of the present invention, there is provided a method of fabricating a semiconductor device,

the method using the gas processing device.

### BRIEF DESCRIPTION OF THE SEVERAL VIEWS OF THE DRAWING

FIG. 1 schematically shows a configuration of a gas processing device in accordance with one embodiment of the present invention; and

FIG. 2 schematically shows a configuration of a generic gas processing device.

### DETAILED DESCRIPTION OF THE EMBODIMENT

According to one embodiment of the present invention, there is provided a gas processing device comprising:

a sub pump which reduces the pressure of gases containing reactive components and then exhausts the gases;

a plasma decomposition device which decomposes the reactive components contained in the gases exhausted from the sub pump and then exhausts the gases; and

a main pump which reduces the pressure of the gases exhausted from the plasma decomposition device and then exhausts the gases.

In this case, “reactive components” are components that react within the plasma decomposition device and “gases that comprise reactive components” are gases in which reactive components are a portion thereof, or gases that comprise nothing but reactive components.

The gas processing device of this embodiment makes it possible to control the pressure of gases within the plasma decomposition device by the sub pump, due to the above-described configuration. In other words, it becomes possible to control the pressure of gases within the plasma decomposition device to a pressure suitable for reactions, by controlling the reduced-pressure state of the gases within the plasma decomposition device by the sub pump. As a result, the gas decomposition capability of the plasma decomposition device can be increased.

The gas processing device of this embodiment can further include the configurations described below.

(A) The plasma decomposition device may be disposed between the main pump and the sub pump.

(B) The pressure of the gases exhausted from the sub pump to the plasma decomposition device may be adjusted by adjusting the number of rotational speed of the main pump. This configuration makes it possible to strictly control the pressure within the plasma decomposition device.

(C) A pipeline may be provided between the main pump and the plasma decomposition device, and the pressure of the gases exhausted from the sub pump to the plasma decomposition device may be adjusted by adjusting the aperture of the pipeline. This configuration makes it possible to strictly control the pressure of the gases exhausted from the sub pump to the plasma decomposition device.

(D) Additive gases that are capable of reacting with the reactive components may be further introduced into the plasma decomposition device.

The gas processing device of this embodiment can be applied to a method of fabricating a semiconductor device.

In such a case, the sub pump is connected to a reaction device, and the gases of a pressure that has been reduced by the sub pump can be exhausted from the reaction device. This configuration ensures that, even if there is any increase in the pressure of gases within the plasma decomposition device as a result of the plasma decomposition reactions within the plasma decomposition device, the increase in gas pressure does not have a direct effect on the reaction device. This ensures the stable operation of the reaction device.

The gas processing device of this embodiment is described below in detail, with reference to the accompanying figures.

1. Configuration of Gas Processing Device

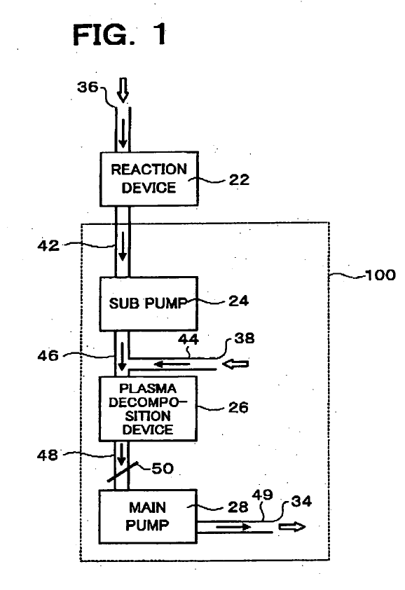

The configuration of gas processing device 100 of this embodiment is shown schematically in FIG. 1.

The gas processing device 100 of this embodiment has a function of breaking down or decomposing the reactive components within gases, by a plasma decomposition device 26. Specifically, this gas processing device 100 comprises a sub pump 24, the plasma decomposition device 26, and a main pump 28, as shown in FIG. 1. The plasma decomposition device 26 is disposed between the sub pump 24 and the main pump 28. More specifically, a reaction device 22 and the sub pump 24 are connected by a pipeline 42, the sub pump 24 and the plasma decomposition device 26 are connected by another pipeline 46, and the plasma decomposition device 26 and the main pump 28 are also connected by a pipeline 48.

Note that this embodiment is described with respect to a case in which the reactive components are PFCs. The description of this embodiment also relates to the use of the gas processing device in the fabrication of semiconductor devices. Specifically, after PFCs have been used to generate reactions in the reaction device 22 during the process of fabricating semiconductor devices, gases comprising as reactive components non-reacted PFCs and fluoride compounds generated by the reactions are exhausted from the reaction device 22. After these gases have been introduced into the plasma decomposition device 26, the reactive components within the gases are broken down within the plasma decomposition device 26.

The sub pump 24 and the main pump 28 are provided for adjusting the pressure of gases within the plasma decomposition device 26. In particular, since the plasma decomposition device 26 is connected to the sub pump 24 by the pipeline 46 and to the main pump 28 by the pipeline 48, it is possible to precisely adjust the pressure of the gas exhausted from the sub pump 24 to the plasma decomposition device 26 by adjusting the rotational speed of the main pump 28. As a result, it is possible to adjust the pressure of gases within the plasma decomposition device 26 more strictly.

In this case, it is also possible to adjust the pressure of gases exhausted from the sub pump 24 to the plasma decomposition device 26 by adjusting the aperture of the pipeline 48 provided between the main pump 28 and the. plasma decomposition device 26 instead of adjusting the rotational speed of the main pump 28, or by adjusting the aperture of the pipeline 48 in addition to adjusting the rotational speed of the main pump 28. This makes it possible to strictly control the pressure of gases exhausted from the sub pump 24 to the plasma decomposition device 26.

A load adjustment valve 50 could be provided in the pipeline 48, as shown by way of example in FIG. 1. The aperture of the pipeline 48 can be adjusted by opening and closing this load adjustment valve 50. In other words, the pressure of gases exhausted from the sub pump 24 to the plasma decomposition device 26 can be adjusted strictly by adjusting the opening and closing of this load adjustment valve 50.

To ensure efficient plasma decomposition of the reactive components (PFCs and fluoride compounds) within the plasma decomposition device 26, it is desirable to set the pressure of the gases within the plasma decomposition device 26 to be within a suitable range. The suitable pressure range for these gases will vary with factors such as the types and densities of the reactive components comprised within the gases and the temperature within the plasma decomposition device 26. If the pressure of the gases within the plasma decomposition device 26 is too low, it will be difficult to produce collisions between the molecules of the reactive components and the plasma. As a result, it will be difficult to initiate plasma decomposition, and there is a danger that the plasma decomposition efficiency will drop. If the pressure of the gases within the plasma decomposition device 26 is too high, on the other hand, it will not be possible to obtain sufficient plasma to break down the reactive components comprised within the gases, again leading to the danger that the plasma decomposition efficiency will drop.

The gas processing device 100 of this embodiment makes it possible to increase the efficiency with which the reactive components are broken down within the plasma decomposition device 26, by using the sub pump 24 and the main pump 28 to adjust the pressure of the gases within the plasma decomposition device 26 to be within a suitable range.

The gases used within the reaction device 22 are PFCs employed during the process of fabricating semiconductor devices, such as in dry etching and CVD. Specifically, PFCs are introduced into the reaction device 22 from a gas entrance 36, as shown in FIG. 1. As a result of the reactions within the reaction device 22, gases comprising non-reacted PFCs and fluoride compounds generated by the reactions are exhausted to the sub pump 24.

The sub pump 24 is connected to the reaction device 22. After the gases exhausted from the reaction device 22 are introduced to the sub pump 24, this sub pump 24 reduces the pressure of those gases to a high vacuum state. The main pump 28 exhausts the gases from the plasma decomposition device 26 after reducing the pressure thereof. The pressure difference of the gases before and after they are exhausted by the sub pump 24 is larger than the pressure difference of the gases before and after the pressure is reduced by the main pump 28. More specifically, the sub pump 24 can reduce the pressure of the gases exhausted from the reaction device 22 to a high vacuum state (such as a pressure of 1 mTorr or less). The main pump 28 can further reduce the pressure of the gases exhausted from the plasma decomposition device 26 to several tens of mTorr to several hundreds of mTorr.

The plasma decomposition device 26 is a plasma decomposition device that uses a low-pressure discharge plasma method. A plasma decomposition device of the low-pressure discharge plasma method necessitates the gases introduced into the plasma decomposition device being in a reduced-pressure state to generate a discharge plasma. For that reason, it is necessary to provide a pressure-reducing device (in this case, the sub pump 24 and the main pump 28). A plasma decomposition device using the low-pressure discharge plasma method has an advantage of enabling the efficient decomposition of organic gases at a comparatively low temperature. The plasma decomposition device 26 could use various different plasma generation methods, such as an induced coupled plasma (ICP) method or a radio frequency (RF) method by a parallel-plate-device.

The plasma decomposition device 26 breaks down the reactive components (non-reacted PFCs and fluoride compounds) comprised within the gases exhausted from the sub pump 24. The gasses exhausted from the sub pump 24 are introduced into the plasma decomposition device 26 together with a additive gas from a additive gas entrance 38, if necessary. This additive gas is used to promote reactions with the reactive components within the plasma decomposition device 26.

Specifically, the sub pump 24 and the plasma decomposition device 26 are connected by the pipeline 46, and another pipeline 44 is connected partway along this pipeline 46, as shown in FIG. 1. This makes it possible to introduce the gases exhausted from the sub pump 24 into the plasma decomposition device 26 together with the additive gas. Note that the sub pump 24 could be a booster pump (such as a roots pump or a screw pump).

A gas comprising oxygen atoms or hydrogen atoms as structural components could be used as the additive gas. By using such gases as additive gases, it is possible to break the reactive components (PFCs and fluoride compounds) comprised within the gases exhausted from the sub pump 24 down into CO₂ or CO and H₂O, and F₂. Specifically, a gas such as O₂, H₂O, H₂, or CO could be used as the additive gas. In addition, this gas could be introduced into the plasma decomposition device 26 in a state in which it comprises a gas that is inert with respect to the reactive components, such as nitrogen or argon.

If the reactive component of the gas introduced into the plasma decomposition device 26 comprises C₂F₆ (a PFC) and the additive gas is O₂, by way of example, the reaction C₂F₆+O₂→2CO+3F₂ proceeds within the plasma decomposition device 26. In other words, the C₂F₆ decomposes to carbon monoxide gas (CO) and fluorine gas (F₂).

With the above-described reaction, the molecular number of the molecules increases after the reaction than before. If similar reactions are induced with the other components within the gases introduced to the plasma decomposition device 26, the reactive components within the plasma decomposition device 26 will themselves experience an increase in the molecular number of the molecules, in comparison with the state before the reactions. This will result in the pressure of the gases within the plasma decomposition device 26 being higher after the reaction than before.

The main pump 28 reduces the pressure of the gases exhausted from the plasma decomposition device 26 then exhausts them. As previously described, the pressure of the gases during the exhausting from the plasma decomposition device 26 is higher than the pressure of the gases during the introduction into the plasma decomposition device 26.

Note that means for removing acidic gases (such as F₂ or HF) could be provided before the gas is exhausted from the main pump 28. Examples of this means for removing acidic gases include a method of bubbling the gases through an alkaline water-based solution, a method of passing the gasses through an adsorbent material, and a method of breaking the gases down by heat.

2. Operation of the Gas Processing Device

The description now turns to the operation of this gas processing device 100.

The gases exhausted from the reaction device 22 are introduced through the pipeline 42 into the sub pump 24, together with the additive gas that is introduced from the additive gas entrance 38. Non-reacted PFCs and fluoride compounds are contained within the gases exhausted from the reaction device 22, as the reactive components.

The gases introduced into the sub pump 24 are then reduced in pressure to a high vacuum state (such as 1 mm or less) by the sub pump 24, then are exhausted. In this case, the exhausted gases are introduced into the plasma decomposition device 26 through the pipeline 46. The additive gas in this case is introduced into the plasma decomposition device 26 from the additive gas entrance 38 and through the pipeline 44 and the pipeline 46. The reactive components are broken down by the plasma in the plasma decomposition device 26 and also react with the additive gas (see the previous example concerning C₂F₆). This converts the non-reacted PFCs and fluoride compounds into gases of lower molecular weights (such as CO, H₂O, and F₂).

After the post-reaction gases have been exhausted from the plasma decomposition device 26, they are introduced into the main pump 28 through the pipeline 48. The gases exhausted from the plasma decomposition device 26 are reduced in pressure then exhausted from the main pump 28. Specifically, the gases exhausted from the plasma decomposition device 26 are reduced in pressure and exhausted by the main pump 28. The gases are then exhausted through a pipeline 49 to a gas exhaust orifice 34. In this case, acidic gases within the exhausted gases can be removed by one of the previously described methods.

3. Operating Effect

Before discussing the operating effects of the gas processing device 100 of this embodiment, the description first turns to the configuration of a generic gas processing device 200, by way of comparison.

3.1. Configuration of Generic Gas Processing Device 200

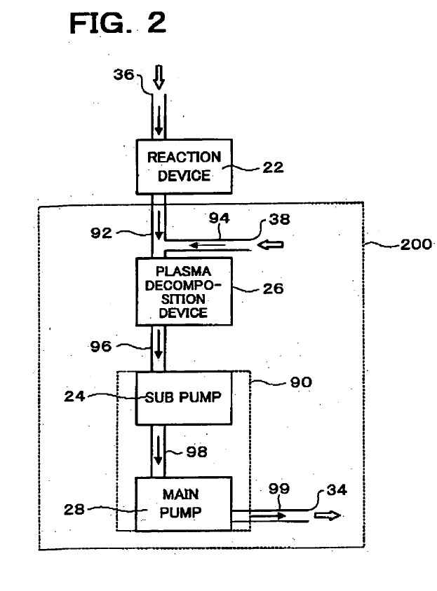

The configuration of the generic gas processing device 200 is shown schematically in FIG. 2. This gas processing device 200 comprises the plasma decomposition device 26 that uses a low-pressure discharge plasma method, in a similar manner to the gas processing device 100 of this embodiment. Note that this gas processing device 200 is also described with reference to an example in which, after PFCs have been used for reactions within the reaction device 22, the gases including the non-reacted PFCs and the fluoride compounds generated by the reactions as reactive components are exhausted from the reaction device 22.

This gas processing device 200 comprises the plasma decomposition device 26 together with the reaction device 22 and a dry pump 90. The reaction device 22 is connected to the plasma decomposition device 26 and the plasma decomposition device 26 is connected to the dry pump 90. In other words, the reaction device 22 is connected in series with the plasma decomposition device 26 and the dry pump 90. The reaction device 22 and the plasma decomposition device 26 are connected by a pipeline 92 and the plasma decomposition device 26 and the dry pump 90 are connected by a pipeline 96.

The dry pump 90 comprises the sub pump 24 and the main pump 28. In the dry pump 90, the sub pump 24 and the main pump 28 are connected in series and the sub pump 24 is connected to the plasma decomposition device 26. This sub pump 24 and main pump 28 are connected by a pipeline 98.

With this gas processing device 200, the reactive components within the gases exhausted from the reaction device 22 are subjected to plasma decomposition within this plasma decomposition device 26 after the gases exhausted from the reaction device 22 are introduced into the plasma decomposition device 26 together with the additive gas introduced from the additive gas entrance 38, by the dry pump 90 putting the gases in the plasma decomposition device 26 into a reduced-pressure state. The post-reaction gases are subsequently reduced in pressure by the dry pump 90 and are exhausted from the gas exhaust orifice 34 through the pipeline 99.

With this gas processing device 200, the plasma decomposition device 26 is disposed between the reaction device 22 and the dry pump 90. Thus the pressure of the gases introduced into the plasma decomposition device 26 is mainly determined by the pressure of the gases exhausted from the reaction device, the pressure of the additive gas introduced from the additive gas entrance 38, and the capabilities of the dry pump 90. For that reason, it is difficult to adjust the gas pressures independently immediately before their introduction into the plasma decomposition device 26.

In particular, it could happen that the pressure within the reaction device 22 is adjusted to several tens of mTorr, depending on the types of reactions within the reaction device 22. In such a case, if gases of a pressure that has been adjusted to several tens of mTorr are exhausted from the reaction device 22, the pressure thereof will be further reduced by the dry pump 90, so that the gases immediately before their introduction into the plasma decomposition device 26 have a pressure that is at an extremely high vacuum state (a state that is extremely close to a vacuum). As described previously, it is necessary to ensure that the pressure within the plasma decomposition device 26 is set to be within a suitable range, to ensure that the plasma decomposition of the reactive components (PFCs and fluoride compounds) within the plasma decomposition device 26 proceeds efficiently. However, with this generic gas processing device 200, the plasma decomposition device 26 is disposed between the reaction device 22 and the dry pump 90 as described above, so that the pressure within the plasma decomposition device 26 is at state that is lower than necessary. In other words, since there is a state in which it is difficult for collisions to occur between the molecules of the reactive components and the plasma, it is difficult to induce plasma decomposition of the reactive components. This can lead to a problem in that the efficiency of the plasma decomposition of the reactive components within the plasma decomposition device 26 deteriorates.

In a similar manner to the plasma decomposition device 26 of the gas processing device 100, there are reactions within the plasma decomposition device 26 of the gas processing device 200 between the additive gas introduced from the additive gas entrance 38 and the reactive components within the gases exhausted from the sub pump 24, creating new gases. As a result, the pressure within the plasma decomposition device 26 will increase. In other words, the pressure of the gases within the plasma decomposition device 26 after the reactions between the reactive components and the additive gas will be greater than the pressure of the gases within the plasma decomposition device 26 before the reactions, as described previously (in the example of the reaction between C₂F₆ and O₂). With this gas processing device 200, the plasma decomposition device 26 and the reaction device 22 are connected by the pipeline 92 (see FIG. 2). For that reason, the pressure within the reaction device 22 will be changed by the increase in the pressure of the gases within the plasma decomposition device 26 created by these reactions, which raises a problem in that the reactions within the reaction device 22 might be hindered thereby.

3.2. Operating Effect of the Gas Processing Device 100 of This Embodiment

In contrast thereto, the gas processing device 100 of this embodiment comprises the sub pump 24 that reduces the pressure of gases comprising reactive components then exhausts them, the plasma decomposition device 26 that decomposes the reactive components comprised in the gases exhausted from the sub pump 24 then exhausts them, and the main pump 28 that reduces the pressure of the gases exhausted from the plasma decomposition device 26 then exhausts them. More specifically, the plasma decomposition device 26 is disposed between the sub pump 24 and the main pump 28. This ensures that the pressure of the gas introduced into the plasma decomposition device 26 can be controlled by the main pump 28. In other words, it is possible to control the pressure of the gases within the plasma decomposition device 26 to a pressure that is suitable for reactions, by controlling the reduced-pressure state of the gases within the plasma decomposition device 26 by the main pump 28. As a result, the gas decomposition capabilities of the plasma decomposition device 26 can be increased.

In addition, the sub pump 24 of the gas processing device 100 is disposed between the reaction device 22 and the plasma decomposition device 26. This ensures that any increase in gas pressure due to an increase in the pressure of the gases within the plasma decomposition device 26 created by the plasma decomposition reaction within the plasma decomposition device 26 does not affect the reaction device 22 directly. This makes it possible to ensure the stable operation of the reaction device 22.

The present invention is not limited to the above-described embodiment and thus various modifications thereto are possible. For example, the present invention comprises configurations that are substantially the same as those described with respect to this embodiment (such as configurations having the same function, method, and result or configurations having the same objective and result). In addition, the present invention comprises configurations in which components are substituted that are not described with respect to this embodiment. The present invention further comprises configurations that achieve the same operating effect as the configuration described with reference to this embodiment, or configurations that achieve the same objective thereof. Furthermore, the present invention comprises configurations in which known techniques are added to the configuration described with reference to this embodiment.

This embodiment was described as relating to the decomposition of PFCs by a plasma decomposition device, by way of example, but it should be obvious to those skilled in the art that the substances broken down by the plasma decomposition device are not limited to PFCs and thus other gases comprising reactive components such as organic halogen compounds such as CFCs can be included therein.

The gas processing device of the present invention described in this embodiment is used in the process of fabricating semiconductor devices, but it is not limited thereto and thus the gas processing device of the present invention can be used in other applications. Examples of these other applications include the removal of harmful substances from gases exhausted from product painting plants, solvent treatment facilities, printing plants, automobile paint plant, gasoline stations, and other worksites. In these cases, the gases include the harmful substances as reactive components. Furthermore, it should be obvious that not only harmful substances but also components that react with the additive gas can be broken down by the gas processing device of the present invention.

What is claimed is:

1. A gas processing device comprising:
a sub pump which reduces the pressure of gases containing reactive components and then exhausts the gases;
a plasma decomposition device which decomposes the reactive components contained in the gases exhausted from the sub pump and then exhausts the gases; and
a main pump which reduces the pressure of the gases exhausted from the plasma decomposition device and then exhausts the gases.

2. The gas processing device as defined in claim 1,
wherein the plasma decomposition device is disposed between the main pump and the sub pump.

3. The gas processing device as defined in claim 1,
wherein the pressure of the gases exhausted from the sub pump to the plasma decomposition device is adjusted by adjusting the rotational speed of the main pump.

4. The gas processing device as defined in claim 1,
wherein a pipeline is provided between the main pump and the plasma decomposition device, and
wherein the pressure of the gases exhausted from the sub pump to the plasma decomposition device is adjusted by adjusting the aperture of the pipeline.

5. The gas processing device as defined in claim 1,
wherein additive gases that are capable of reacting with the reactive components are further introduced into the plasma decomposition device.

6. The gas processing device as defined in claim 3,
wherein a pipeline is provided between the main pump and the plasma decomposition device, and
wherein the pressure of the gases exhausted from the sub pump to the plasma decomposition device is adjusted by adjusting the aperture of the pipeline.

7. A method of fabricating a semiconductor device,
the method using the gas processing device as defined in claim 1.

8. The method of fabricating a semiconductor device as defined in claim 7,
wherein the sub pump is connected to a reaction device, and
wherein the gases that have been reduced in pressure by the sub pump are exhausted from the reaction device.
